(19) United States
(12) Patent Application Publication
(10) Pub. No.: US 2009/0319840 A1
(43) Pub. Date: Dec. 24, 2009

(54) SEMICONDUCTOR MEMORY DEVICE AND TEST METHOD THEREOF

(76) Inventors: Tokumasa Hara, Kawasaki-shi (JP); Keiji Maruyama, Kawasaki-shi (JP); Yutaka Shirai, Yokohama-shi (JP); Hidetoshi Saito, Yamato-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/487,250

(22) Filed: Jun. 18, 2009

(30) Foreign Application Priority Data
Jun. 24, 2008 (JP) 2008-164950

(51) Int. Cl. G11C 29/12; H03M 13/05; G06F 11/10; G06F 11/27

(52) U.S. Cl. 714/718; 714/773; 714/763; 714/E11.032; 714/E11.169

(57) ABSTRACT

A semiconductor memory device includes a nonvolatile memory functioning as a main memory unit, a volatile memory functioning as a buffer unit of the nonvolatile memory, a controller, an ECC buffer, a parity syndrome circuit, an ECC control circuit, a multiplexer, and an ECC error position decoder.

### CROSS-REFERENCE TO RELATED APPLICATIONS

This application is based upon and claims the benefit of priority from prior Japanese Patent Application No. 2008-164950, filed Jun. 24, 2008, the entire contents of which are incorporated herein by reference.

### BACKGROUND OF THE INVENTION

1. Field of the Invention

The present invention relates to a semiconductor memory device and a test method thereof, which are applied, for example, to a semiconductor memory in which a plurality of kinds of memories are integrated in one chip.

2. Description of the Related Art

An example of a semiconductor memory system, in which a plurality of kinds of memories are integrated in one chip, is OneNAND (trademark) (see, e.g. Jpn. Pat. Appln. KOKAI Publication No. 2006-286179). In the OneNAND, a NAND flash memory, which functions as a main memory unit, and an SRAM or a DRAM, which functions as a buffer unit, are integrated in one chip. In this memory system, a controller, in which a state machine is mounted, controls data transfer between the NAND flash memory and the SRAM (see, e.g. Jpn. Pat. Appln. KOKAI Publication No. 2005-196764).

### BRIEF SUMMARY OF THE INVENTION

According to an aspect of the present invention, there is provided a semiconductor memory device comprising: a nonvolatile memory functioning as a main memory unit; a volatile memory functioning as a buffer unit of the nonvolatile memory; a controller which controls data transfer between the nonvolatile memory and the volatile memory; an ECC buffer which is provided between the nonvolatile memory and the volatile memory and is capable of storing main data and parity data; a parity syndrome circuit which executes parity generation by using the main data that is written in the ECC buffer from the volatile memory, and executes syndrome generation from the main data and parity data which are read out to the ECC buffer from the nonvolatile memory; an ECC control circuit which controls the parity syndrome circuit and executes timing control of the parity data generation and the syndrome generation; a multiplexer which effects, when a control signal is input from the controller, switching from an output of the parity syndrome circuit to an output of the ECC buffer, and produces the output of the ECC buffer; and an ECC error position decoder which has an input connected to an output of the multiplexer, and has an output connected to the ECC buffer.

According to another aspect of the present invention, there is provided a test method of a semiconductor memory device, comprising: writing a test pattern in a volatile memory; writing the test pattern from the volatile memory into an ECC buffer; generating parity data by using the test pattern which is written in the ECC buffer; transferring the test pattern and the parity data from the ECC buffer to a page buffer of a nonvolatile memory; writing the test pattern and the parity data from the page buffer into the ECC buffer, without writing the test pattern and the parity data from the page buffer into a memory cell array of the nonvolatile memory; and transferring at least the parity data, which is written in the ECC buffer, to the volatile memory.

According to still another aspect of the present invention, there is provided a semiconductor memory device comprising: a nonvolatile memory functioning as a main memory unit; a volatile memory functioning as a buffer unit of the nonvolatile memory; a controller which controls data transfer between the nonvolatile memory and the volatile memory; an ECC buffer which is provided between the nonvolatile memory and the volatile memory and is capable of storing main data and parity data; a logic circuit which sends scan information; a vector memory circuit which stores vector information; a vector read-out circuit which outputs the vector information, which is read out of the vector memory circuit, and the scan information, which is sent from the logic circuit; an expected value read-out circuit which reads out an expected value; a comparison circuit which compares an output of the vector read-out circuit, and the expected value; and a determination circuit which determines an output of the comparison circuit.

### BRIEF DESCRIPTION OF THE SEVERAL VIEWS OF THE DRAWING

FIG. 1 is a block diagram which shows an example of the entire structure of a semiconductor memory device according to a first embodiment of the present invention;

FIG. 2 is a state transition diagram of a main state machine according to the first embodiment;

FIG. 3 is a state transition diagram of a NAND interface state machine according to the first embodiment;

FIG. 4 shows output signal truth values of the NAND interface state machine according to the first embodiment;

FIG. 5 shows a sense command sequence of the NAND interface state machine according to the first embodiment;

FIG. 6 shows a read command sequence of the NAND interface state machine according to the first embodiment;

FIG. 7 shows a program command sequence of the NAND interface state machine according to the first embodiment;

FIG. 8 is a state transition diagram of a main state machine in the case of a structure which does not include a NAND interface state machine;

FIG. 9 is a block diagram showing an ECC engine according to a second embodiment of the invention;

FIG. 10 is a flow chart illustrating a test sequence of a semiconductor memory device according to the second embodiment;

FIG. 11 is a block diagram showing an ECC engine of a semiconductor memory device according to a third embodiment of the invention;

FIG. 12 is a block diagram showing an n SRAM address/timing generating circuit according to the third embodiment;

FIG. 13 shows unit memory areas of a NAND flash memory and an SRAM according to the third embodiment;

FIG. 14 is a flow chart illustrating a test sequence according to the third embodiment;

FIG. 15 is a block diagram showing an example of the entire structure of a semiconductor memory device according to a fourth embodiment of the present invention;

FIG. 16 shows a structure example of a Bist scan circuit of the semiconductor memory device according to the fourth embodiment; and

FIG. 17 is an equivalent circuit diagram showing a structure example of a block which constitutes a NAND cell array in FIG. 1.

### DETAILED DESCRIPTION OF THE INVENTION

Embodiments of the present invention will now be described with reference to the accompanying drawings. In the description below, as an example of a semiconductor memory device, a description is given of a semiconductor memory device in which a NAND flash memory functioning as a main memory unit and an SRAM functioning as a buffer unit are integrated in one chip. In the description below, common parts are denoted by common reference numerals throughout the drawings.

In the case of diverting and assembling an existing NAND flash memory chip in a memory system, if an external interface (I/F) circuit is also diverted, the circuit redesign becomes easier and the efficiency of assembly increases. However, since a state machine is required to send instructions in accordance with external operation specifications of the NAND flash memory chip, there is a tendency that the design of the state machine becomes complex, and the circuit area increases.

As regards a memory system including a buffer unit, there is known a method of enhancing the test efficiency of a memory cell array (see, e.g. Jpn. Pat. Appln. KOKAI Publication No. 2006-79809). On the other hand, in recent years, in the field of memory systems, there has been a demand for a method of enhancing the test efficiency of logic circuits whose areas tend to become larger. As regards the above-described memory system, there are the following points in tendency in connection with the test methods of various logic circuits such as ECC circuits.

### (a) ECC (Error Correcting Code) Circuit Test Method

In general, in a NAND flash memory, data error correction is necessary. Thus, the memory system including a NAND flash memory incorporates an error correction (ECC) circuit. When data is read out of the NAND flash memory, error correction is executed. When data is written in the NAND flash memory, parity generation is executed.

A main circuit, which constitutes the error correction circuit, is, in general, a large-scale logic circuit. In addition, since the operation state of each internal logic gate depends on an input data pattern which is to be error-corrected, the number of combinations of data becomes enormous. It is thus unrealistic to input various data patterns in order to detect a defect in the circuit.

A scan test is an example of the method of testing a defect in the large-scale logic circuit. The scan test can easily generate data patterns for defect detection, and can execute defect detection with high precision. However, since an F/F needs to be replaced with a scan F/F, the circuit area increases and, disadvantageously, a memory tester is not easily adapted to the scan test.

### (b) Self Test (Bist: Built-In Self Test)

In a test of a memory device, most of defects are those of memory cells. Thus, in many cases, in a wafer test, for instance, importance is placed on a test of the entirety of the memory. On the other hand, at the time of this test, logic circuits, such as an ECC engine, for operating the memory, are simply operated. Since the defect ratio of the logic circuit such as an ECC engine is sufficiently low, the test of the logic circuit, in many cases, constitutes a test step which is performed in a package test at a product level stage.

However, as regards the memory device, there is a tendency that the circuit scale of the logic circuit unit, such as an ECC engine, increases. Thus, in a memory device with a relatively small capacity, the defect ratio of the logic circuit has become no longer negligible. Therefore, there is a tendency that a demand becomes stronger for the implementation of a function for efficiently screening the logic circuit at the stage of the wafer test.

In the wafer test, however, in order to increase the number of simultaneous measurements, a dominant method is a self test (Bist test) which can reduce the number of input pins, and can internally execute a test sequence and determination. Thus, disadvantageously, in this environment, it is difficult to directly introduce the scan test method that is widely used in logic devices. Therefore, it is necessary to constitute a scan test circuit which is suited to the self test of the memory device.

### First Embodiment

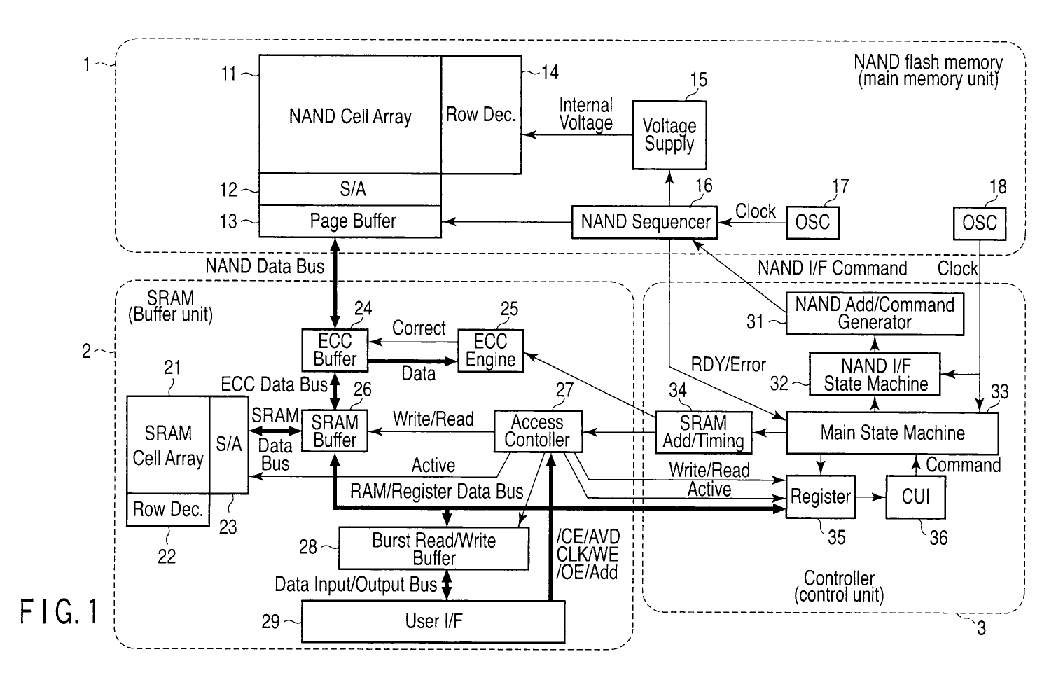

Referring to FIG. 1 to FIG. 8, a description is given of a semiconductor memory device according to a first embodiment of the present invention.

### 1. Structure Example

### 1-1. Example of Entire Structure

To begin with, referring to FIG. 1, a description is given of an example of the entire structure of the semiconductor memory device according to the embodiment.

As shown in FIG. 1, the semiconductor memory device according to the embodiment is configured such that a NAND flash memory 1 functioning as a main memory unit, an SRAM 2 functioning as a buffer unit, and a controller 3 functioning as a control unit for controlling the NAND flash memory 1 and SRAM 2, are integrated in one chip.

### Re: NAND Flash Memory 1

The NAND flash memory 1 includes a memory cell array 11, a sense amplifier 12, a page buffer 13, a row decoder 14, a voltage supply circuit 15, a sequencer 16, and oscillators 17 and 18.

The NAND memory cell array (NAND Cell Array) 11 is a memory cell array of the NAND flash memory 1, and is composed of a plurality of blocks (BLOCK) which are to be described later. Each of the blocks includes a plurality of memory cells which are disposed in a matrix at intersections between bit lines and word lines.

Each of the plural memory cells has a multi-layer structure (not shown) comprising a tunnel insulation film, a charge accumulation layer (floating electrode), an inter-gate insulation film, and a control electrode, which are successively stacked on a semiconductor substrate. For example, each of the memory cells can store 1-bit data in accordance with the variation of a threshold voltage due to the largeness/smallness in the amount of electrons that are injected in the floating electrode. Alternatively, the threshold voltage may be controlled in fine multiple levels, and each of the memory cells may be configured to store data of two bits or more. The memory cell may have a MONOS (Metal Oxide Nitride Oxide Silicon) structure which adopts a method of trapping electrons in a nitride film.

The sense amplifier (S/A) 12 reads out read data of one page of the memory cell array 1. The page (PAGE), in this context, refers to a unit of batch data write or batch data read in the NAND flash memory 1. For example, a plurality of memory cells, which are connected to the same word line, constitute one page. The details of the page will be described later.

The page buffer (Page Buffer) 13 temporarily stores read data or write data of one page in accordance with the control of the sequencer 16. Specifically, at a time of data read, the page buffer 13 temporarily stores one-page data which is read out of the memory cell array 11. At a time of data write, the page buffer 13 temporarily stores one-page data which is to be written in the memory cell array 11.

The row decoder (Row Dec.) 14 selects word lines of the memory cell array 11. In addition, the row decoder 14 applies to the word lines the voltages necessary for data read, write and erase.

The voltage supply circuit (Voltage Supply) 15 generates internal voltages (Internal Voltage) which are necessary for data read, write and erase, in accordance with the control of the sequencer 16, and supplies the voltages to, e.g. the row decoder 14.

The NAND sequencer (NAND Sequencer) 16 receives a command signal (NAND I/F Command) to the NAND flash memory 1, which is issued from a NAND address/command generating circuit (NAND Add/Command Generator) 31, and executes overall control of the NAND flash memory 1, such as data write, read and erase in the NAND flash memory 1.

The oscillator (OSC) 17 generates an internal clock (Clock) for internal control of the NAND sequencer (NAND Sequencer) 16.

The oscillator (OSC) 18 generates an internal clock (Clock) for internal control of a main state machine (Main State Machine) 33.

### Re: SRAM 2

The SRAM 2 includes an SRAM memory cell array 21, a row decoder 22, a sense amplifier 23, an ECC buffer 24, an ECC engine 25, an SRAM buffer 26, an access controller 27, a burst read/write buffer 28, and a user interface 29.

The SRAM memory cell array (SRAM Cell Array) 21 is used as a buffer for temporarily storing write data which is to be programmed in the NAND flash memory 1, and read data which is loaded from the NAND flash memory 1, and executing data transactions with an external host device. The SRAM memory cell array 21 includes a plurality of memory cells (SRAM cells) which are disposed in a matrix at intersections between word lines and bit lines.

The row decoder (Row Dec.) 22 is a decoder which selects the word lines of the SRAM memory cell array (SRAM Cell Array) 21.

The sense amplifier (S/A) 23 senses/amplifies data which is read out of the SRAM cell to the bit line. In addition, the sense amplifier 23 functions as a load when data in the SRAM buffer 26 is written in the SRAM cells.

The ECC buffer (ECC Buffer) 24 is positioned between the SRAM 2 and the NAND page buffer (NAND Page Buffer) 13, and temporarily stores data for an ECC process (error correction at a time of data loading; parity generation at a time of data programming). In other wards, the ECC buffer 24 is provided between the nonvolatile memory 11 and the volatile memory 21, and the ECC buffer 24 is capable of storing main data and parity data, wherein the logic circuit 25 is an ECC engine which executes error correction by generating a parity data by using the main data transferred to the ECC buffer 24 from the volatile memory 21, and generating a syndrome by using the main data and parity data transferred to the ECC buffer 24 from the nonvolatile memory 11.

The ECC engine (ECC Engine) 25 executes error correction of data (Data) which is input from the ECC buffer 24, and outputs the corrected data (Correct) back to the ECC buffer 24.

The SRAM buffer (SRAM Buffer) 26 temporarily stores data in order to execute data read and data write from/to the SRAM memory cell array (SRAM Cell Array) 21.

The access controller (Access Controller) 27 receives addresses and control signals which are input from the user interface (User I/F) 29, and executes control necessary for the respective internal circuits.

The burst read/write buffer (Burst Read/Write Buffer) 28 is a buffer which temporarily stores data in order to execute data read/write.

The user interface (User I/F) 29 supports interface standards which are similar to those of NOR flash memories. The user interface 29 executes input/output of addresses, control signals and data from/to the external host device. Examples of the control signals are a chip enable signal /CE for activating the entirety of the semiconductor memory device, an address valid signal /AVD for latching an address, a clock CLK for burst read, a write enable signal /WE for activating a write operation, and an output enable signal /OE for activating the output of data to the outside.

### Re: Controller 3

The controller 3 includes a NAND address/command generating circuit 31, a NAND interface state machine (second state machine) 32, a main state machine (first state machine) 33, an SRAM address/timing generating circuit 34, a register 35, and a command user interface 36.

The NAND address/command generating circuit (NAND Add/Command Generator) 31 issues, where necessary, control signals (NAND I/F commands), such as an address and a command, to the NAND sequencer 16, in the internal sequence operation which is controlled by the NAND interface state machine 32. The NAND address/command generating circuit 31 issues addresses/commands according to the external interface standard of the NAND flash memory 1.

For example, the NAND address/command generating circuit 31 controls the NAND flash memory 1 via a chip enable signal line (CEn_NAND), a write enable signal line (WEn_NAND), a command latch enable signal line (CLEn_NAND), an address latch enable signal line (ALEn_NAND) and a read enable signal line (REn_NAND). In addition, the NAND address/command generating circuit 31 transfers addresses and commands to the NAND flash memory 1 via a data input signal line (DIN_NAND: NAND Data Bus).

The NAND interface state machine (NAND I/F State Machine) 32 controls the issuance of the control signal (NAND I/F Command) (to be described later), which is generated by the NAND address/command generating circuit 31, in sync with the internal clock (Clock) from the oscillator 18 in accordance with the control of the main state machine 33. Specifically, the NAND interface state machine 32 has a command cycle generating function of generating a command cycle to the NAND flash memory 1. In other words, the NAND interface state machine 32 is a state machine which is positioned in a lower level layer of the main state machine 33 that controls data transfer, and controls the issuance of commands to the NAND flash memory 1 which is the main memory unit.

To be more specific, the NAND interface state machine 32 detects, in the state transition of the main state machine 33, the state of the main state machine 33 in which a command needs to be issued to the NAND flash memory 1, and starts to operate to issue a command cycle corresponding this state.

On the other hand, the main state machine 33 transitions to the next state, upon receiving the information that the command cycle generation of the NAND interface state machine 32 is completed. If state transition of the main state machine 33 occurs, all registers in the NAND interface state machine 32 are cleared and the operation thereof is initialized. Thereby, such a hierarchical structure is formed that in one of the states of the main state machine 33, the state transition of the NAND interface state machine 32 is completed.

There are many functions which are supported by the main state machine 33, such as load (Load), program (Program) and erase (Erase). There are also many kinds of commands which are issued to the NAND flash memory 1 during the operation of such functions. With similar schemes, the hierarchical structure between the main state machine 33 and the NAND interface state machine 32, which is the state machine for NAND, can be realized.

The main state machine (Main State Machine) 33, as described above, receives the internal command signal (Command) that is issued from the command user interface 36, and controls the internal sequence operation corresponding to the kind of the internal command signal.

In the semiconductor memory device according to the present embodiment, the NAND flash memory 1 functions as the main memory unit, and the SRAM 2 functions as the buffer unit. Accordingly, when data is to be read out of the NAND flash memory 1 to the outside, data which is read out of the memory cell array 11 of the NAND flash memory 1 is first stored in the SRAM memory cell 21 via the page buffer 13. Then, the data in the SRAM memory cell array 21 is transferred to the user interface 29 and is output to the outside.

On the other hand, when data is to be stored in the NAND flash memory 1, data which is delivered from the outside is first stored in the SRAM memory cell array 21 via the user interface 29. Then, the data in the SRAM memory cell array 21 is transferred to the page buffer 13 and is written in the memory cell array 11.

In the description below, the operation from the read-out of data from the memory cell array 11 to the transfer of the data to the SRAM memory cell array 21 via the page buffer 13 is referred to as “load (Load)” of data. In addition, the operation until the data in the SRAM memory cell array 21 is transferred to the user interface 29 via the burst read/write buffer 28 (to be described later) is referred to as “read (Read)” of data.

Besides, the operation until the data, which is to be stored in the NAND flash memory 1, is transferred from the user interface 29 to the SRAM memory array 21 via the burst read/write buffer 28, is referred to as “write (Write)” of data. In addition, the operation until the data in the SRAM memory cell array 21 is transferred to the page buffer 13 and is written in the memory cell array 11 of the NAND flash memory 1 is referred to as “program (Program)” of data.

The SRAM address/timing generating circuit (SRAM Add/Timing) 34 generates control signals of address/timing to the SRAM 2, where necessary, in the internal sequence operation that is controlled by the main state machine 33.

The register (Register) 35 is a register for setting the operation state of the function. A part of the external address space is allocated to the register 35, and the register 35 stores, for instance, a command which is sent from the outside via the user interface 29.

The command user interface (CUI) 36 recognizes that a function execution command has been delivered, on the basis of the write of predetermined data in the register (Register) 35, and issues an internal command signal (Command).

### 1-2. Re: Main State Machine 33

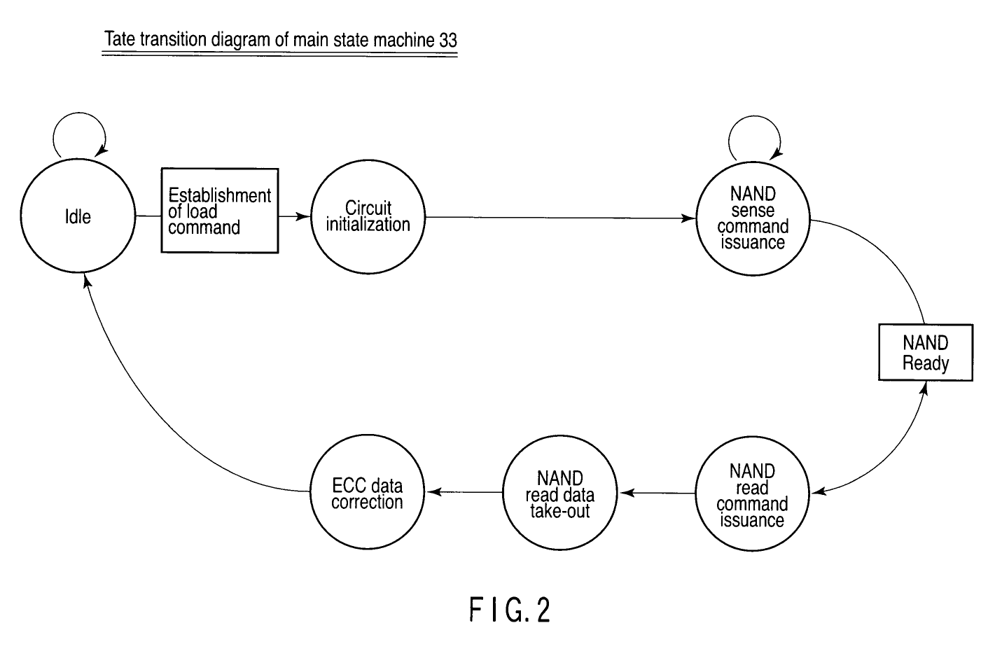

Next, referring to FIG. 2, the state transition of the main state machine 33 is described. In this description, the load function is described by way of example. As regards the other functions (e.g. program function), the hierarchical structure between the main state machine 33 and the NAND interface state machine 32 that is the state machine for NAND can be realized with similar schemes.

As shown in FIG. 2, to start with, if a load (Load) command is set in the register 35 via the user interface 29, the command user interface 36 detects this command setting, and generates an internal command (Command). Thereby, the load command is established. If the load command is established, the main state machine 33 transitions from an idle state (Idle) to a circuit initialization state. In the circuit initialization state, the main state machine 33 initializes the respective circuits which are necessary for the load function.

Then, the main state machine 33 transitions to a NAND sense command issuance state. The NAND interface state machine 32 detects that the main state machine 33 has transitioned to the NAND sense command issuance state, and starts to operate. The NAND interface state machine 32 generates a sense command cycle, and issues to the NAND address/command generating circuit 31 a request for the issuance of a sense command.

The NAND sequencer 16, which has received the sense command from the NAND address/command generating circuit 31, initializes the internal circuits of the NAND flash memory 1, and stores one-page data, which is read out of the memory cell array 11, in the page buffer 13. If the data storage in the page buffer 13 is completed, the NAND sequencer 16 reports NAND ready (RDY) to the main state machine 33.

The main state machine 33, which has been informed of the finish of the sense command cycle generation of the NAND interface state machine 32 and the NAND ready from the NAND sequencer 16, transitions to a NAND read command issuance state. Since the state transition of the main state machine 33 has occurred, all registers in the NAND interface state machine 32 are cleared and the operation thereof is initialized.

Then, the NAND interface state machine 32, upon detecting that the main state machine 33 has transitioned to the NAND read command issuance state, generates a read command cycle, and issues to the NAND address/command generating circuit 31 a request for issuance of a read command. If the read command cycle generation of the NAND interface state machine 32 is finished, the main state machine 33 transitions to a NAND read data take-out state.

In the case where the main state machine 33 has transitioned to the NAND read data take-out state, there is no need to issue a command to the NAND flash memory 1, and thus the NAND interface state machine 32 generates no command cycle. The main state machine 33 executes an internal operation which is necessary for taking data into the buffer unit 2 via the data bus (NAND Data Bus).

If the data take-out to the buffer unit 2 is finished, the main state machine 33 transitions to an ECC data correction state. In the case where the main state machine 33 has transitioned to the ECC data correction state, there is no need to issue a command to the NAND flash memory 1, and thus the NAND interface state machine 32 generates no command cycle.

The main state machine 33 executes an operation that is necessary for error correction of the data that is stored in the ECC buffer 24. If the error correction is finished and the data is stored in the SRAM memory cell array 21, the main state machine 33 returns to the idle state. By the above-described state transition, the main state machine 33 executes the load function.

### 1-3. Re: NAND Interface State Machine 32

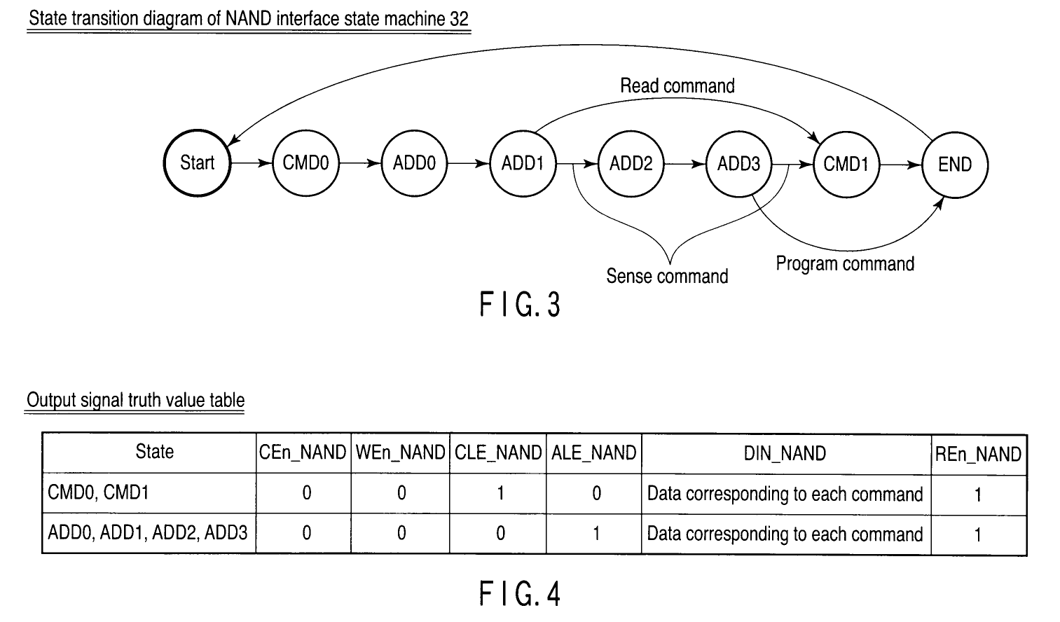

Next, referring to FIG. 3 to FIG. 7, the NAND interface state machine 32 is described. The NAND interface state machine 32 detects the state transition of the main state machine 33 and, if command issuance to the NAND flash memory 1 is needed, generates a predetermined command cycle.

### State Transition

FIG. 3 illustrates the state transition of the NAND interface state machine 32. As shown in FIG. 3, in the case where the NAND interface state machine 32 detects that the main state machine 33 has transitioned to the NAND sense command issuance state, the NAND interface state machine 32 issues, after the internal circuits of the NAND flash memory 1 are initialized, a command cycle by a sequence of a command CMD0, addresses ADD0 to ADD3 and a command CMD1 in succession. If the generation of the command cycle is finished, the NAND interface state machine 32 executes a command issuance finishing process.

On the other hand, in the case where the NAND interface state machine 32 detects that the main state machine 33 has transitioned to the NAND read command issuance state, the NAND interface state machine 32, after the internal circuits of the NAND flash memory 1 are initialized, a command cycle by a sequence of a command CMD0, addresses ADD0 and ADD1 and a command CMD1 in succession. If the generation of the command cycle is finished, the NAND interface state machine 32 executes a command issuance finishing process.

Although not shown in FIG. 3, in the case where the NAND interface state machine 32 detects that the main state machine 33 has transitioned to a NAND program command issuance state (NAND page buffer load command state), the NAND interface state machine 32, after the internal circuits of the NAND flash memory 1 are initialized, a command cycle by a sequence of a command CMD0 and addresses ADD0 to ADD3 in succession. If the generation of the command cycle is finished, the NAND interface state machine 32 executes a command issuance finishing process.

These addresses and commands are issued to the NAND flash memory 1 from the NAND address/command issuing circuit 31 which receives control from the NAND interface state machine 32.

### Output Signal Truth Values

Upon receiving control from the NAND interface state machine 32, the NAND address/command generating circuit 31 generates control signals (NAND I/F Command) such as addresses and commands to the NAND sequencer 16. The output signal truth values of the control signals (NAND I/F Command) are as shown in FIG. 4.

As shown in FIG. 4, in the case where the commands CMD0 and CMD1 and addresses ADD0 to ADD3 are input to the NAND flash memory 1, the chip enable signal line (CEn_NAND) is set at a “0” state. By setting the chip enable signal line (CEn_NAND) at the “0” state, the NAND flash memory 1 is activated. In the meantime, in the case where the chip enable signal line (CEn_NAND) is set at a “1” state, the NAND flash memory 1 is in a standby state.

In the case where the commands CMD0 and CMD1 and addresses ADD0 to ADD3 are input to the NAND flash memory 1, the write enable signal line (WEn_NAND) is set at the “0” state. The write enable signal line (WEn_NAND) controls the take-in of data from the data input signal line (DIN_NAND).

In the case where the commands CMD0 and CMD1 are input to the NAND flash memory 1, the command latch enable signal line (CLEn_NAND) is set at the “1” state. On the other hand, in the case where the addresses ADD0 to ADD3 are input to the NAND flash memory 1, the command latch enable signal line (CLEn_NAND) is set at the “0” stile. The command latch enable signal line (CLEn_NAND) controls the take-in of commands in a command register (not shown) in the NAND flash memory 1.

In the case where the commands CMD0 and CMD1 are input to the NAND flash memory 1, the address latch enable signal line (ALEn_NAND) is set at the “0” state. In the case where the addresses ADD0 to ADD3 are input to the NAND flash memory 1, the address latch enable signal line (ALEn_NAND) is set at the “1” state. The address latch enable signal line (ALEn_NAND) controls the take-in of addresses in an address register (not shown) in the NAND flash memory 1.

Data corresponding to each command is input to the data input signal line (DIN_NAND). In the case where the commands CMD0 and CMD1 are taken in, data corresponding to the sense command and read command are input. In the case where the addresses ADD0 to ADD3 are taken in, data, such as a block address, a page address and a column address, which indicate a data storage location in the memory cell array 11, are input.

In the case where the commands CMD0 and CMD1 or the addresses ADD0 to ADD3 are input to the NAND flash memory 1, the read enable signal line (REn_NAND) is set at the “1” state. The read enable signal line (REn_NAND) controls the data output from the NAND flash memory 1, and is set at the “0” state when data output is executed.

Next, the sense command sequence, read command sequence and program command sequence of the NAND address/command generating circuit 31 are described in greater detail.

### Sense Command Sequence

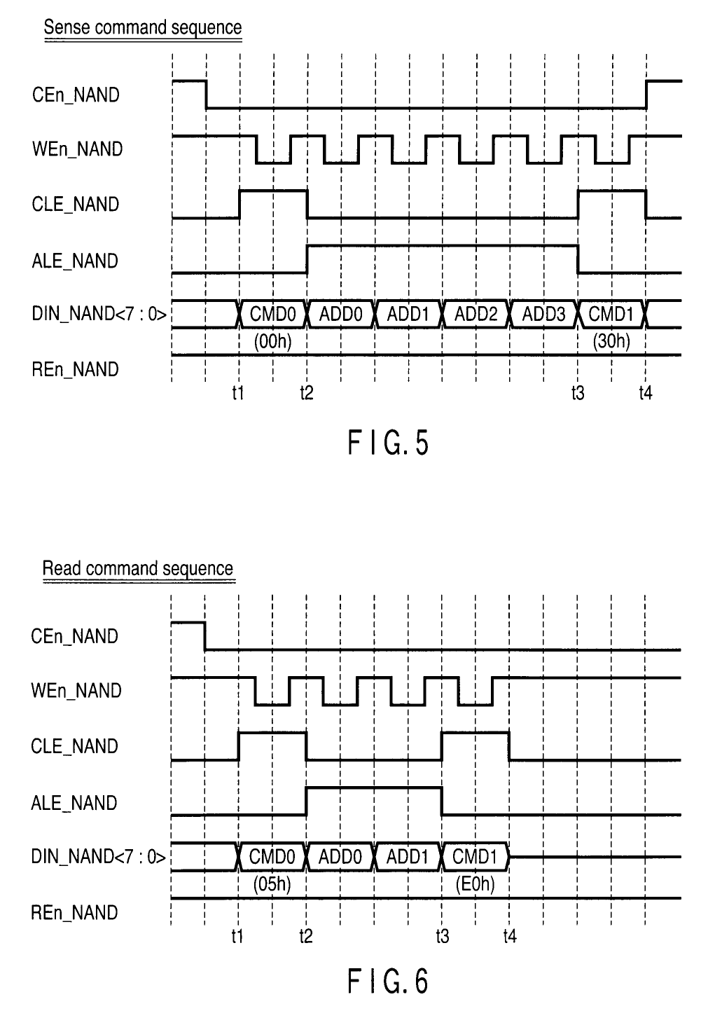

FIG. 5 shows the sense command sequence. If the NAND interface state machine 32 detects that the main state machine 33 has transitioned to the NAND sense command issuance state and the sense command and addresses are input to the NAND sequencer 16 from the NAND address/command generating circuit 31, one-page data is read out into the page buffer 13. As shown in FIG. 5, in this command sequence, the read enable signal line (REn_NAND) is always at the “1” state.

At time point t1, if the command latch enable signal line (CLE_NAND) rises to the “1” state when the chip enable signal line (CEn_NAND) is at the “0” state, the write enable signal line (WEn_NAND) is at the “1” state and the address latch enable signal line (ALE_NAND) is at the “0” state, the command CMD0 (0h) is taken in from the data input signal line (DIN_NAND<7:0>).

Subsequently, at time point t2, if the address latch enable signal line (ALE_NAND) rises to the “1” state when the chip enable signal line (CEn_NAND) is at the “0” state, the write enable signal line (WEn_NAND) is at the “1” state and the command latch enable signal line (CLE_NAND) is at the “0” state, the address ADD0 is taken in from the data input signal line (DIN_NAND<7:0>).

Then, by the same command sequence at time point t2, the addresses ADD1 to ADD3 are successively taken in. In this example, the addresses of the data, which is read out of the memory cell array 11, are designated in four cycles. However, the number of cycles of the address designation is not limited to four, and is properly set in accordance with, for example, the capacity of the NAND flash memory 1.

Thereafter, at time point t3, if the command latch enable signal line (CLE_NAND) rises to the “1” state when the chip enable signal line (CEn_NAND) is at the “0” state, the write enable signal line (WEn_NAND) is at the “1” state and the address latch enable signal line (ALE_NAND) is at the “0” state, the command CMD1 (30h) is taken in from the data input signal line (DIN_NAND<7:0>).

Subsequently, at time point t4, the sense command sequence ends when the chip enable signal line (CEn_NAND) is at the “0” state, the write enable signal line (WEn_NAND) is at the “1” state, the command latch enable signal line (CLE_NAND) is at the “0” state, and the address latch enable signal line (ALE_NAND) is at the “0” state.

### Read Command Sequence

FIG. 6 shows the read command sequence. If the NAND interface state machine 32 detects that the main state machine 33 has transitioned to the NAND read command issuance state and the read command and addresses (column addresses) are input to the NAND sequencer 16 from the NAND address/command generating circuit 31, the data that is stored in the page buffer 13 is serially output in the order of input column addresses. As shown in FIG. 6, in this command sequence, the read enable signal line (REn_NAND) is always at the “1” state.

At time point t1, if the command latch enable signal line (CLE_NAND) rises to the “1” state when the chip enable signal line (CEn_NAND) is at the “0” state, the write enable signal line (WEn_NAND) is at the “1” state and the address latch enable signal line (ALE_NAND) is at the “0” state, the command CMD0 (05h) is taken in from the data input signal line (DIN_NAND<7:0>).

Subsequently, at time point t2, if the address latch enable signal line (ALE_NAND) rises to the “1” state when the chip enable signal line (CEn_NAND) is at the “0” state, the write enable signal line (WEn_NAND) is at the “1” state and the command latch enable signal line (CLE_NAND) is at the “0” state, the address ADD0 is taken in from the data input signal line (DIN_NAND<7:0>).

Then, by the same command sequence at time point t2, the address ADD1 is taken in. In the read command sequence, since the column addresses corresponding to one-page data, which is stored in the page buffer 13, are designated, the number of cycles necessary for the address designation is less than in the sense command sequence, and the take-in of data is completed, for example, in two cycles.

Thereafter, at time point t3, if the command latch enable signal line (CLE_NAND) rises to the “1” state when the chip enable signal line (CEn_NAND) is at the “0” state, the write enable signal line (WEn_NAND) is at the “1” state and the address latch enable signal line (ALE_NAND) is at the “0” state, the command CMD1 (E0h) is taken in from the data input signal line (DIN_NAND<7:0>).

Subsequently, at time point t4, the read command sequence ends when the chip enable signal line (CEn_NAND) is at the “0” state, the write enable signal line (WEn_NAND) is at the “1” state, the command latch enable signal line (CLE_NAND) is at the “0” state, and the address latch enable signal line (ALE_NAND) is at the “0” state.

### Program Command Sequence

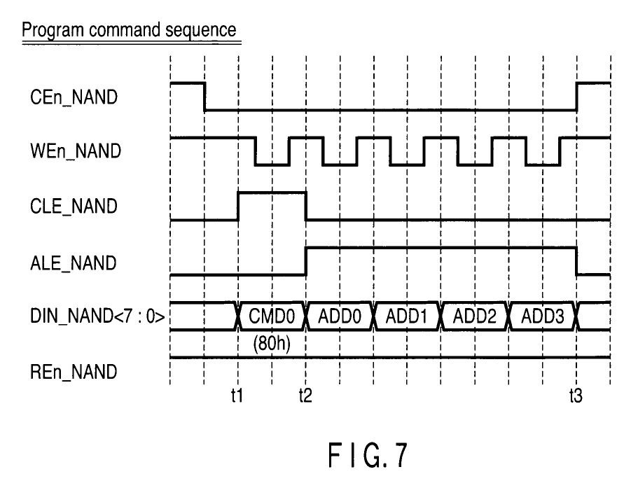

FIG. 7 shows the program command sequence. If the NAND interface state machine 32 detects that the main state machine 33 has transitioned to the NAND program command issuance state (NAND page buffer load command state) and the program command (page buffer load command), addresses and data are input to the NAND flash memory 1, the data is transferred to the page buffer 13. As shown in FIG. 7, in this command sequence, the read enable signal line (REn_NAND) is always at the “1” state.

At time point t1, if the command latch enable signal line (CLE_NAND) rises to the “1” state when the chip enable signal line (CEn_NAND) is at the “0” state, the write enable signal line (WEn_NAND) is at the “1” state and the address latch enable signal line (ALE_NAND) is at the “0” state, the command CMD0 (80h) is taken in from the data input signal line (DIN_NAND<7:0>).

Subsequently, at time point t2, if the address latch enable signal line (ALE_NAND) rises to the “1” state when the chip enable signal line (CEn_NAND) is at the “0” state, the write enable signal line (WEn_NAND) is at the “1” state and the command latch enable signal line (CLE_NAND) is at the “0” state, the address ADD0 is taken in from the data input signal line (DIN_NAND<7:0>).

Then, by the same command sequence at time point t2, the addresses ADD1 to ADD3 are successively taken in.

Thereafter, at time point t3, the chip enable signal line (CEn_NAND) rises to the “1” state, the write enable signal line (WEn_NAND) is at the “1” state, the command latch enable signal line (CLE_NAND) is at the “0” state, and the address latch enable signal line (ALE_NAND) is at the “0” state.

Subsequently, although not shown in FIG. 3 to FIG. 7, the data is stored in the page buffer 13 via the data input signal line (DIN_NAND<7:0>), and after the program command (cell array program command: 10h) is input, the data write to the memory cell array 11 is started. The data write to the memory cell array 11 involves the repetition of data read-out to the page buffer 13 and a verify operation. After the data write is completed or the number of times of repetition reaches a predetermined value, the program command sequence is finished.

### 2. Advantageous Effects of the First Embodiment

According to the semiconductor memory device of the first embodiment, at least the following advantageous effect (1) can be obtained.

(1) Design can be simplified, and the circuit area can advantageously be reduced.

As has been described above, the semiconductor memory device according to the present embodiment includes the NAND interface state machine 32 which has the command cycle generating function of generating a command cycle to the NAND flash memory 1. In other words, the NAND interface state machine 32 is a state machine which is positioned in a lower level layer of the main state machine 33 that controls data transfer, and controls the issuance of commands to the NAND flash memory 1 which is the main memory unit.

To be more specific, as shown in FIG. 2 and FIG. 3, the NAND interface state machine 32 detects, in the state transition of the main state machine 33, the state of the main state machine 33 in which a command needs to be issued to the NAND flash memory 1, and starts to operate to issue a command cycle corresponding this state.

As shown in FIG. 2 and FIG. 3, the main state machine 33 transitions to the next state, upon receiving the information that the command cycle generation of the NAND interface state machine 32 is completed. If state transition of the main state machine 33 occurs, all registers in the NAND interface state machine 32 are cleared and the operation thereof is initialized. Thereby, such a hierarchical structure is formed that in one of the states of the main state machine 33, the state transition of the NAND interface state machine 32 is completed.

There are many functions which are supported by the main state machine 33, such as load (Load), program (Program) and erase (Erase). There are also many kinds of commands which are issued to the NAND flash memory 1 during the operation of such functions. With similar schemes, the hierarchical structure between the main state machine 33 and the NAND interface state machine 32, which is the state machine for NAND, can be realized.

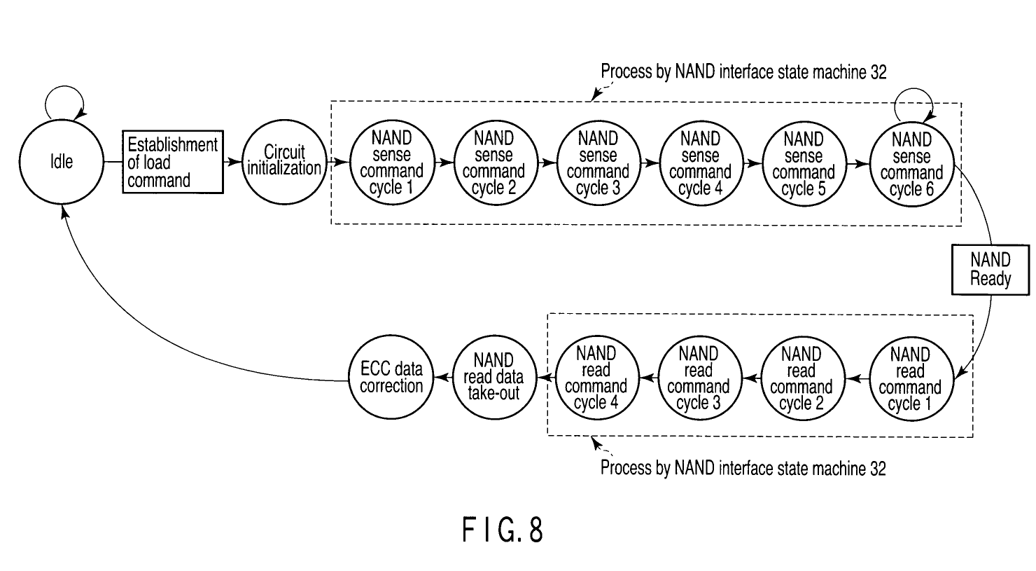

For example, in the case of a structure which does not include the NAND interface state machine 32, the state transition of the main state machine 33 is as shown in FIG. 8. Although the load function is described by way of example, the same applies to the other functions (e.g. program function).

In the structure which does not include the NAND interface state machine 32, a NAND sense command cycle 1 to a NAND sense command cycle 6 and a NAND read command cycle 1 to a NAND read command cycle 4, which are boxed by broken lines in FIG. 8, need to be described one by one, and these command cycles can hardly be shared between different functions. Hence, disadvantageously, the number of states greatly increases, the design of the state machine becomes complex, and the circuit area increases.

In the present embodiment, however, the NAND interface state machine 32, which controls the issuance of commands to the NAND flash memory 1 which is the main memory unit, is provided in the lower level layer of the main state machine 33 that controls data transfer. Thus, at least the NAND sense command cycle 1 to NAND sense command cycle 6 and the NAND read command cycle 1 to NAND read command cycle 4, which are boxed by broken lines in FIG. 8, can be simplified and described as the NAND sense command issuance state and the NAND read command issuance state, respectively.

As a result, in the NAND interface state machine 32 that constitutes the lower level layer of the main state machine 33, as shown in FIG. 3, the command cycles, which need to be issued to the NAND flash memory 1, can be shared between different functions. Therefore, advantageously, the design of the state machines 32 and 33 can be simplified, and the circuit area can be reduced.

### Second Embodiment

### An Example Relating to an ECC Circuit Test

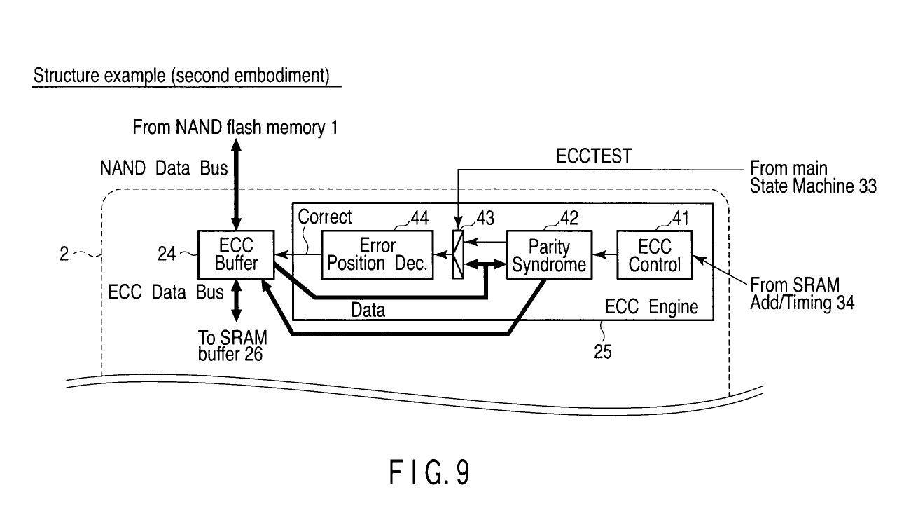

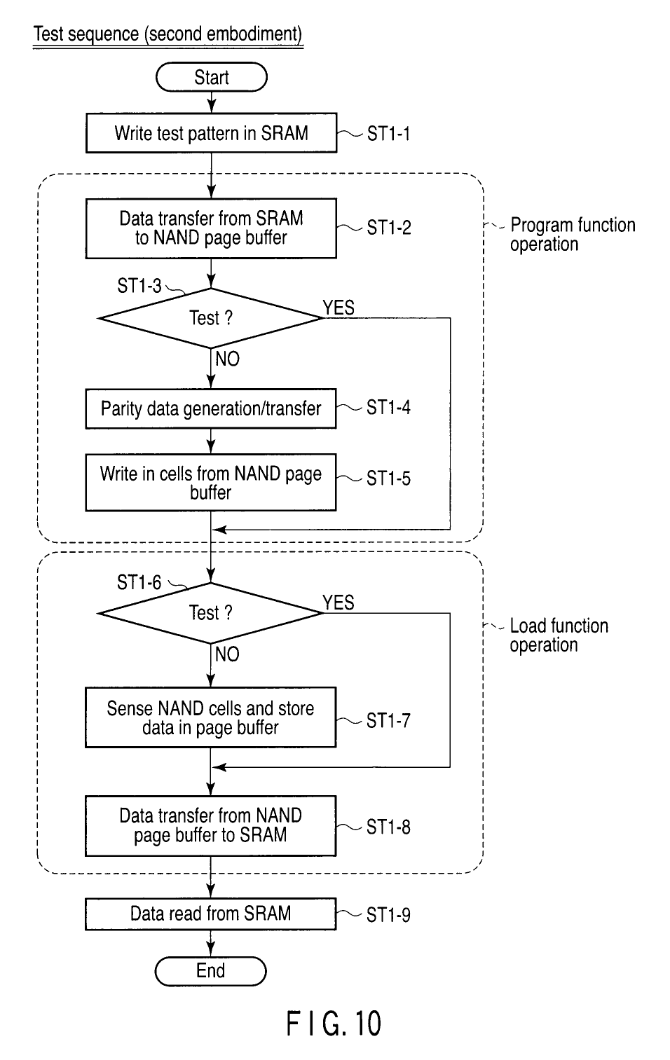

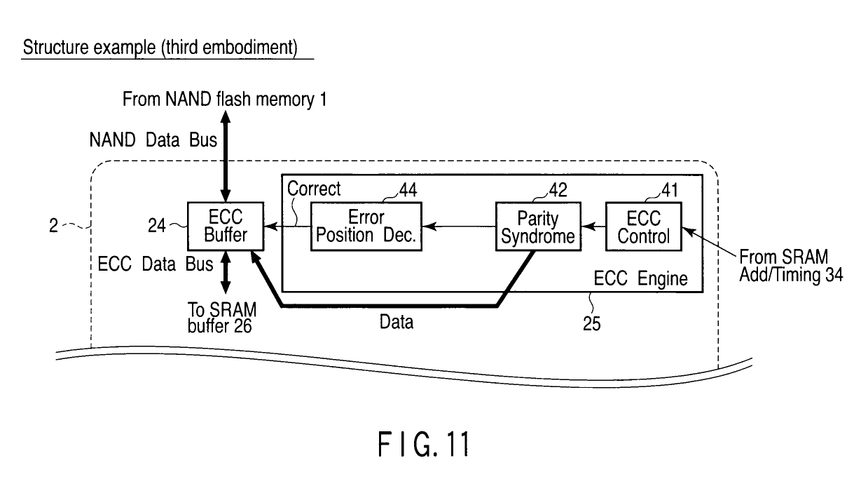

Next, referring to FIG. 9 and FIG. 10, a semiconductor memory device according to a second embodiment of the present invention is described. This embodiment relates to a test of an error correcting code (ECC) circuit. A detailed description of the parts common to those of the above-described first embodiment is omitted here.

### <Structure Example (ECC Engine 25)>

Referring to FIG. 9, a description is given of a structure example of the semiconductor memory device according to the present embodiment. As shown in FIG. 9, the ECC engine 25 in this embodiment comprises an ECC control circuit 41, a parity syndrome 42, a multiplexer 43 and an error position decoder 44.

The ECC control circuit (ECC Control) 41 controls the parity syndrome 42 so as to execute timing control of data input/output of the ECC buffer 24 and parity/syndrome generation, in accordance with an address and a timing, which are received from the SRAM address/timing generating circuit 34.

The parity syndrome (Parity Syndrome) 42 receives control of the ECC control circuit 41, and receives the input of data (Data) for an ECC process from the ECC buffer 24 at a time of program, thereby executing parity generation. The generated parity is transferred to a parity hold area in the ECC buffer 24, and is stored in the page buffer 13 via the data bus (NAND Data Bus). In addition, the parity syndrome 42 receives control of the ECC control circuit 41, and receives the input of data (Data) and parity for the ECC process from the ECC buffer 24 at a time of load, thereby executing syndrome generation.

In accordance with a control signal (ECCTEST) which is input from the main state machine 33, the multiplexer 43 effects switching between the output of the parity syndrome 42 and the output from the ECC buffer 24, and delivers the output, which is selected by switching, to the error position decoder 44. To be more specific, in a normal error correction operation, the multiplexer 43 receives a syndrome output of the parity syndrome 42, and delivers the syndrome output to the error position decoder 44.

On the other hand, at a time of a test which is described later, in accordance with the control signal (ECCTEST), the multiplexer 43 effects switching to the data pattern from the ECC buffer 24, whose defect detection ratio and decoder output value are understood in advance, and delivers the data pattern to the error position decoder 44. The output result of the error position decoder 44 is written back to the SRAM memory cell 21 via the ECC buffer 24. By comparing a read-out (Read) output value from the SRAM memory cell array 21 with an expected value in an external tester, a test of the error position decoder 44 can be performed.

The error position decoder (Error Position Dec.) 44 receives the syndrome input from the parity syndrome 42 via the multiplexer 43, and outputs the address (Correct) of the bit (bit), in which data error is present, to the ECC buffer 24.

### <Test Sequence>

Next, an ECC test sequence of the semiconductor memory device according to the second embodiment is described with reference to FIG. 10. In the test sequence in the present embodiment, since applied use is made of the program function operation and load function operation, a description is made of steps in the operations of both functions, which are not executed in the test.

### (ST1-1)

To Start with, a Test Pattern is Written in the SRAM 2.

To be more specific, the external tester, which has received a user's instruction, writes a test pattern in the SRAM 2 via the user interface 29. Then, the access controller 27 sets a NAND address/SRAM address (Add) for program in the register 35. Subsequently, the external tester sets the program command in the register 35 via the user interface 29. Then, if the command is written in the register 35, the command user interface 36 detects the command, and generates an internal command signal (Command). Thus, the program command is established.

### Program Function Operation

### (ST1-2)

Subsequently, Data Transfer is Executed from the SRAM 2 to the NAND page buffer 13.

To be more specific, responding to the establishment of the program command signal, the main state machine 33 is activated. Then, after the necessary circuit initialization is executed, the main state machine 33 transitions to the NAND program command issuance state (specifically, the NAND page buffer load command state). The NAND page buffer load command state, in this context, is a state in which data transfer from the SRAM 2 to the page buffer 13 is controlled.

Upon detecting the transition of the main state machine 33 to the NAND page buffer load command issuance state, the NAND interface state machine 32 generates a program command cycle (page buffer load command cycle) and issues to the NAND address/command generating circuit 31 a request for the generation of a program command (page buffer load command).

Subsequently, the main state machine 33 issues a read clock to the SRAM 2, reads out the data from the SRAM 2 to the ECC data bus 26, and transfers the data to the ECC buffer 24.

### (ST1-3)

Subsequently, the Main State Machine 33 Determines whether a test is conducted or not. If it is determined that a test is conducted, the program function operation is finished, and control advances to step ST1-6.

### (ST1-4)

If a Test is not Determined in Step ST1-3, the main state machine 33 transitions to the parity data generation state. In other words, a normal program function operation is continued. In the present embodiment, a part of the program function operation is diverted to the test sequence, as described above.

To be more specific, the main state machine 33 issues an ECC parity generation start control signal to the ECC control circuit 41 via the SRAM address/timing generating circuit 34. The parity syndrome 42 writes the generated parity in the ECC buffer 24. The parity data, which is written in the ECC buffer 24 is transferred to the page buffer 13.

### (ST1-5)

Subsequently, the Main State Machine 33 transitions to the NAND program command issuance state (specifically, the NAND cell array program command state). Upon detecting the transition of the main state machine 33 to the NAND cell array program command state, the NAND interface state machine 32 generates a program command cycle (cell array program command cycle) and issues a request for the generation of the program command (cell array program command) to the NAND address/command generating circuit 31.

The NAND sequencer 16, which has received the program command (cell array program command) from the NAND address/command generating circuit 31, writes the data, which is stored in the NAND page buffer 13, into the memory cell array 11.

To be more specific, the main state machine 33 and NAND interface state machine 32 read out the data, to which the parity data has been added, to the NAND data bus, and transfers the data to the page buffer 13. Then, the NAND address/command generating circuit 31 issues a command to the NAND sequencer 16 so as to execute program at the NAND address that is set in the register 35.

Subsequently, upon receiving the program command (cell array program command), the NAND sequencer 16 executes necessary circuit initialization, and then controls the voltage supply circuit 15, row decoder 14, sense amplifier 12 and page buffer 13 in order to execute a program operation at the designated address, thus programming the data of the page buffer 13 in the NAND cell array 11.

Thereafter, the NAND sequencer 16 informs the main state machine 33 of the completion of the program operation of the NAND flash memory 1. Then, the main state machine 33 sets, e.g. a status for monitoring by the user, and finishes the program function operation.

### Load Function Operation

### (ST1-6)

Subsequently, the Main State Machine 33 Determines whether a test is conducted or not. If a test is determined, control advances to step ST1-8.

### (ST1-7)

If a Test is not Determined in Step ST1-6, the main state machine 33 senses the cells in the NAND cell array 11, and stores the sense data in the page buffer 13.

To be more specific, the external tester, which has received the user's instruction, sets in the register 35 the NAND address and SRAM address, which are to be loaded, via the user interface 29.

Subsequently, the external host device, which has received the instruction from the user, sets a load command in the register 35 via the user interface 29. Then, if the command is written in the register 35, the command user interface 36 detects the command and generates an internal command signal. Thus, the load command is established.

Subsequently, responding to the establishment of the load command signal, the main state machine 33 is activated. Then, after the necessary circuit initialization is executed, the main state machine 33 transitions to the NAND sense command state.

Upon detecting the transition of the main state machine 33 to the NAND sense command state, the NAND interface state machine 32 generates a sense command cycle and issues to the NAND address/command generating circuit 31 a request for the generation of a sense command.

Subsequently, the NAND command generating circuit 31 issues a sense command to the NAND sequencer 16 so as to sense the NAND address that is set in the register 35. Then, upon receiving the sense command, the NAND sequencer 16 is activated.

Subsequently, after executing the necessary circuit initialization, the NAND sequencer 16 controls the voltage supply circuit 15, row decoder 14, sense amplifier 12 and page buffer 13 in order to execute a sense operation at the designated address, thereby storing the sense data in the page buffer 13.

Thereafter, the NAND sequencer 16 informs the main state machine 33 of the completion of the sense operation.

### (ST1-8)

Subsequently, the Main State Machine 33 Executes data transfer from the NAND page buffer 13 to the SRAM 2.

To be more specific, responding to the completion of the sense command cycle generation of the NAND interface state machine 32, the main state machine 33 transitions to the NAND read command state. Since state transition has occurred in the main state machine 33, all registers in the NAND interface state machine 32 are cleared and the operation thereof is initialized.

Upon detecting the transition of the main state machine 33 to the NAND read command state, the NAND interface state machine 32 generates a read command cycle and issues to the NAND address/command generating circuit 31 a request for the generation of a read command.

Upon receiving the read command from the NAND address/command generating circuit 31, the NAND sequencer 16 sets the page buffer 13 in a readable state.

Subsequently, the main state machine 33 transitions to the NAND read data take-out state, issues a read command (clock) to the NAND sequencer 16, reads out the data in the page buffer 13 to the NAND data bus (NAND Data Bus), and transfers the data to the ECC buffer 24.

Then, the main state machine 33 transitions to the ECC data correction state, and issues an ECC correction start control signal. Upon receiving the control signal, the parity syndrome 42 generates a syndrome.

Subsequently, in accordance with a control signal (ECCTEST) that is input from the main state machine 33, the multiplexer 43 effects switching between the output of the parity syndrome 42 and the output of the ECC buffer 24, and delivers the output, which is selected by the switching, to the error position decoder 44.

Subsequently, on the basis of the syndrome that is generated by the parity syndrome circuit 42, the error position decoder 44 determines a data error position, and inverts erroneous data.

Then, the error-corrected data is read out to the ECC data bus and is transferred to the SRAM buffer 26.

Thereafter, the error-corrected data is written in the SRAM memory cell array 21.

Through the above-described steps ST1-6 to ST1-8, the load function operation is completed.

### (ST1-9)

At Last, the Error-Corrected Data is Read Out of the SRAM memory cell array 21.

To be more specific, the external tester, which has received an instruction from the user, reads out the error-corrected data from the SRAM memory cell array 21 via the user interface 29.

### Advantageous Effects of the Second Embodiment

With the above-described semiconductor memory device and the test method thereof according to the second embodiment, the same advantageous effect (1) as described above can be obtained. Furthermore, in the present embodiment, at least the following advantageous effect (2) can be obtained.

(2) The speed of the test operation can advantageously be increased.

The present embodiment includes the ECC engine 25 which comprises the ECC control circuit 41, parity syndrome 42, multiplexer 43 and error position decoder 44.

In accordance with the control signal (ECCTEST) which is input from the main state machine 33, the multiplexer 43 effects switching between the output of the parity syndrome 42 and the output of the ECC buffer 24, and delivers the output, which is selected by switching, to the error position decoder 44. To be more specific, in the normal error correction operation of the program function operation in steps ST1-1 to ST1-5, the multiplexer 43 delivers the output of the parity syndrome 42 to the error position decoder 44.

However, at the time of the test of the load function operation in steps ST1-6 to ST1-8, in accordance with the control signal (ECCTEST), the multiplexer 43 effects switching to the data pattern from the ECC buffer 24, whose defect detection ratio and decoder output value are understood in advance, and delivers the data pattern to the error position decoder 44. By comparing the output value with the expected value, the test of the error position decoder 44 can be performed.

To be more specific, in the program function operation in the sequence (ST1-1 to ST1-5) in FIG. 10, the data write sequence of data write to the NAND flash memory 1 is diverted, and data transfer is executed from the SRAM 2 to the page buffer 13. In the normal operation, data write is subsequently executed from the page buffer 13 to the NAND flash memory 1, but the data write is not executed at the time of the test.

In addition, in usual cases, when data transfer is executed from the SRAM 2 to the page buffer 13 via the ECC engine 25, the parity data that is generated by the ECC engine 25 is added to the input data, and the resultant data is transferred to the NAND page buffer 13. However, when the test method of this embodiment is performed, the addition of the parity data is not executed, and the input data itself is transferred to the page buffer 13.

Next, in the load function operation in the sequence (ST1-6 to ST1-8) in FIG. 10, the data read sequence of data read-out to the NAND flash memory 1 is diverted, and data is transferred from the page buffer 13 to the SRAM 2. In usual operations, the memory cells of the NAND flash memory 1 are sensed, and the sense data is stored in the page buffer 13. At the time of the test of this embodiment, however, this operation is not performed. In addition, in accordance with the control signal (ECCTEST), the output of the parity syndrome 42 is switched to the output of the page buffer 13 as the input to the error position decoder 44. Thereby, the output of the error position decoder 44, to which the data that is first stored in the page buffer 13 is input, is transferred to the SRAM 2.

By the above-described sequence, the data that is stored in the SRAM 2 in advance is used as the test pattern, and the output value of the error position decoder 44 is written back to the SRAM 2. By comparing this data with the expected value, a defect of the error position decoder 44 can be detected.

As has been described above, according to the present embodiment, a defect of the error position decoder 44 can be detected, not via the NAND flash memory 1, but via the ECC buffer 24. As a result, the speed of the test operation can advantageously be increased.

For example, in the case of the present embodiment, the speed of the test operation can be increased to such a degree that the test time is about 10 μm, compared to the test time of 250 μm in the case of the test via the NAND flash memory 1. In short, in the case of this embodiment, the test time can advantageously be reduced to about 1/25.

### Third Embodiment

### Another Example Relating to the ECC Test

Next, referring to FIG. 11 to FIG. 13, a description is given of a semiconductor memory device and a test method thereof according to a third embodiment of the invention. The third embodiment, like the second embodiment, relates to a test of an error correcting code (ECC) circuit. A detailed description of the parts common to those in the second embodiment is omitted here.

### <Structure Example (ECC Engine 25)>

Referring to FIG. 11, a structure example of the semiconductor memory device according to this embodiment is described. As shown in FIG. 11, the present embodiment differs from the second embodiment with respect to the structure of the ECC engine 25 which is included in the SRAM 2.

The ECC engine 25 comprises an ECC control circuit 41, a parity syndrome 42 and an error position decoder 44. Specifically, unlike the second embodiment, the ECC engine 25 of the third embodiment does not need the multiplexer 43. The functions of the ECC control circuit 41, parity syndrome 42 and error position decoder 44 are the same as in the second embodiment.

In the present embodiment, a test of the parity syndrome 42 in the ECC engine 25 can be performed at high speed by a test sequence which will be described later.

### <Structure Example (SRAM Address/Timing Generating Circuit 34)>

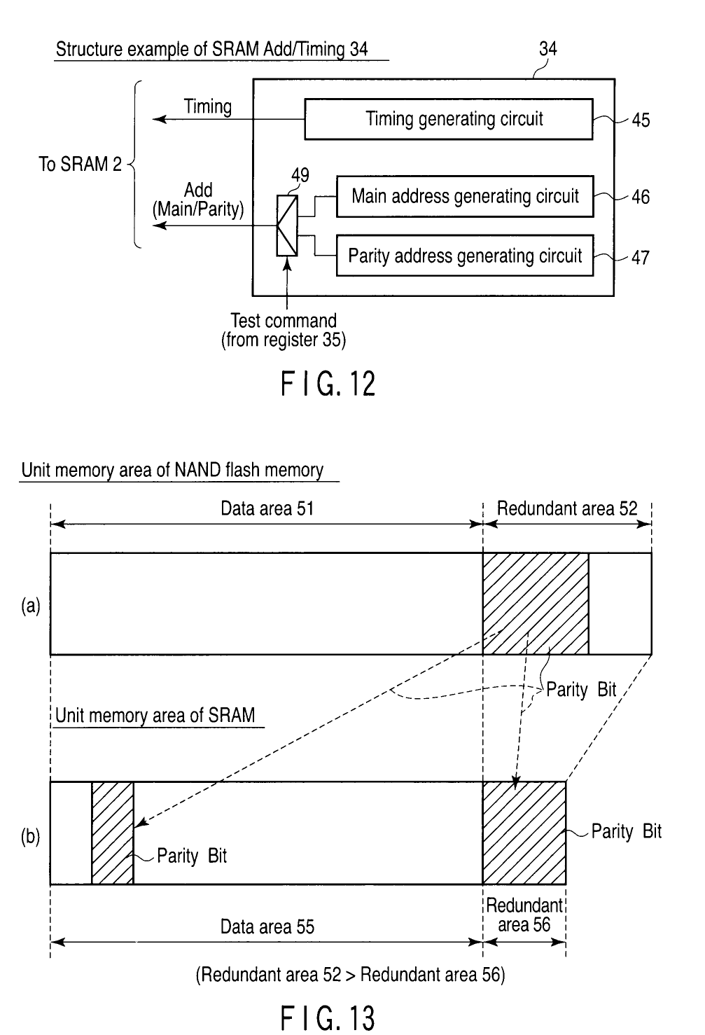

As shown in FIG. 12, the SRAM address/timing generating circuit 34 according to the present embodiment comprises a timing generating circuit 45, a main address generating circuit 46, a parity address generating circuit 47 and a multiplexer 49.

The timing generating circuit 45 outputs a predetermined timing (Timing) to the SRAM 2.

The main address generating circuit 46 outputs a main address (Add Main) to the multiplexer 49.

The parity address generating circuit 47 outputs a parity address (Add Parity) to the multiplexer 49.

The multiplexer 49 effects switching from the main address (Add Main) to the parity address (Add Parity) if a test command is input as a control signal from the register 35, and outputs the parity address to the SRAM 2.

According to the above-described structure, although the test sequence will be described later in detail, the data can be switched so that the parity bit (Parity Bit or Parity Data) is transferred to the address of the SRAM 2 to which main data is to be transferred in usual cases.

Therefore, as shown in FIG. 13, all parity data can be transferred to the SRAM 2, even in the case where although there is an SRAM area which is allocated to parity bits (Parity Bit) as external specifications, the actual parity bits require a size greater than this SRAM area.

For example, (a) in FIG. 13 indicates a unit memory area (page) of the NAND flash memory 1, and (b) in FIG. 13 indicates a unit memory area of the SRAM 2. As shown in FIG. 13, the unit memory area comprises a data area 51, 55 and a redundant area 52, 56. The size of the redundant area 52 of the NAND flash memory 1 is greater than the size of the redundant area 56 of the SRAM 2 (redundant area 52>redundant area 56). Thus, there may be a case in which all parity bits (Parity Bit) cannot be transferred to the SRAM 2.

According to the structure of the present embodiment, however, a part of the parity bits (Parity Bit) can be transferred to the data area 55 of the SRAM 2. Therefore, even in the case where the parity bits, which are to be transferred, have a size greater than the size of the redundant area 56 of the SRAM 2, all parity data can be transferred to the SRAM 2.

### <Test Sequence>

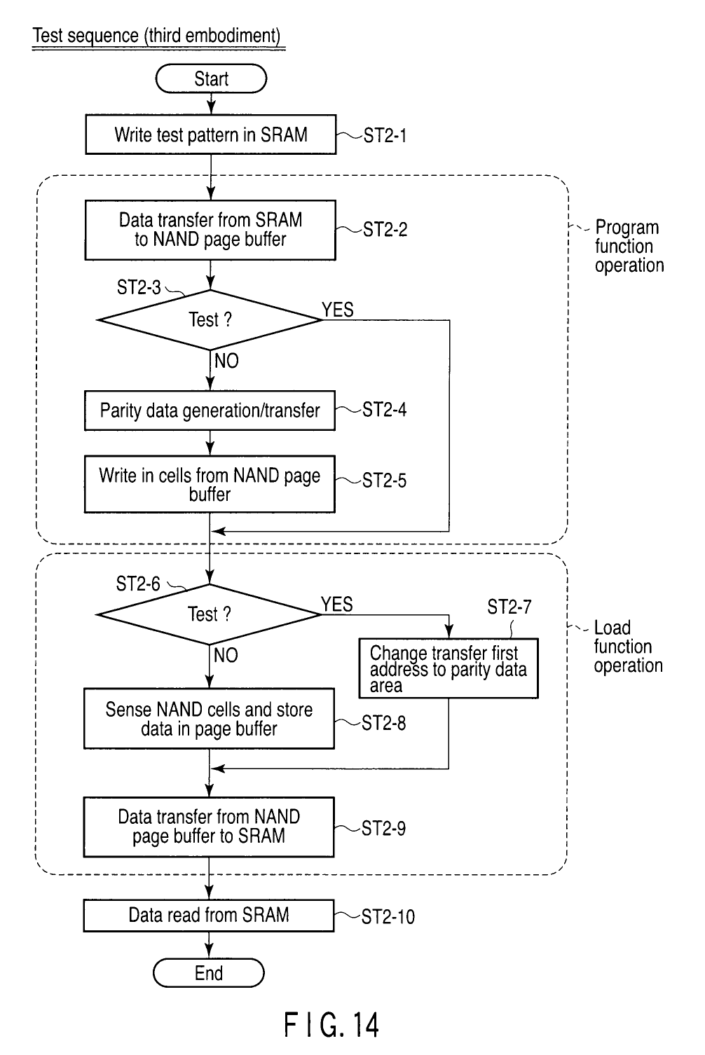

Next, referring to FIG. 14, a description is given of a test sequence of the semiconductor memory device according to the present embodiment. A description of the parts, which are substantially common to those in the second embodiment, is omitted here.

Step ST2-1 is substantially equal to the corresponding step in the second embodiment, so a detailed description thereof is omitted. In the present embodiment, however, a data pattern, in which the output value of parity data is understood in advance, is input.

### Program Function Operation

The present third embodiment differs from the second embodiment with respect to step ST2-3 and step ST2-4. In order to execute a test of the parity syndrome 42, it is necessary to once transfer the parity data, which is generated by the parity syndrome 42 on the basis of input data, to the page buffer 13. Accordingly, in step ST2-3, parity data is generated and data transfer to the page buffer 13 is executed. After the main data and parity data are stored in the page buffer 13, it is determined in step ST2-4 whether a test is conducted or not.

If a test is determined in step ST2-4, like the second embodiment, the write of main data and parity bit in the cells of the memory cell array 11 from the page buffer 13, which is executed in step ST2-5, is skipped.

### Load Function Operation

The third embodiment differs from the second embodiment with respect to step ST2-7. Specifically, in step ST2-7, the SRAM 2 receives an output from the SRAM address/timing generating circuit 34, and changes the transfer address to the parity data area.

To be more specific, if a test command from the register 35 is input as a control signal, the multiplexer 49 effects switching from the main address (Add Main) to the parity address (Add Parity), and outputs the parity address to the SRAM 2. Thus, the data can be switched so that the parity bit (Parity Bit or Parity Data) is transferred to the address of the SRAM 2 to which main data is to be transferred in usual cases.

As a result, as shown in FIG. 13, all parity data can be transferred to the SRAM 2, even in the case where although there is an SRAM area which is allocated to parity bits (Parity Bit) as external specifications, the actual parity bits require a size greater than this SRAM area.

Subsequently, in step ST2-9, the parity data is transferred from the NAND page buffer 13 to the SRAM 2.

Thereafter, in step ST2-10, by comparing the read (Read) output value from the SRAM memory cell array 21 with the expected value in the external tester, the test of the parity syndrome 42 can be executed.

If a test is determined in step ST2-6, like the second embodiment, the sense of the cells in the memory cell array 11 and the storage of the sense data in the page buffer 13, which are executed in step ST2-8, is skipped.

### Advantageous Effects of the Third Embodiment

With the above-described semiconductor memory device according to the present embodiment, the same advantageous effect (1) as described above can be obtained. Furthermore, in the present embodiment, at least the following advantageous effect (3) can be obtained.

(3) Even in the case where the parity bits, which are to be transferred, have a size greater than the size of the redundant area 56 of the SRAM 2, all parity data can be transferred to the SRAM 2, and the reliability can be enhanced.

The structure of the present embodiment includes the SRAM address/timing generating circuit 34 which comprises the timing generating circuit 45, main address generating circuit 46, parity address generating circuit 47 and multiplexer 49.

In step ST2-6, if a test command from the register 35 is input as a control signal, the multiplexer 49 effects switching from the main address (Add Main) to the parity address (Add Parity), and outputs the parity address to the SRAM 2. Thus, the data can be switched so that the parity bit (Parity Bit or Parity Data) is transferred to the address of the SRAM 2 to which main data is to be transferred in usual cases.

As shown in FIG. 13, the size of the redundant area 52 of the NAND flash memory 1 is greater than the size of the redundant area 56 of the SRAM 2 (redundant area 52>redundant area 56). Thus, there may be a case in which all parity bits (Parity Bit) cannot be transferred to the SRAM 2.

According to the structure of the present embodiment, however, a part of the parity bits (Parity Bit) can be transferred to the data area 55 of the SRAM 2. Therefore, even in the case where the parity bits, which are to be transferred, have a size greater than the size of the redundant area 56 of the SRAM 2, all parity data can be transferred to the SRAM 2, and the reliability can advantageously be enhanced.

### Fourth Embodiment

### An Example Further Including a Scan Test Circuit which is Suited to Bist

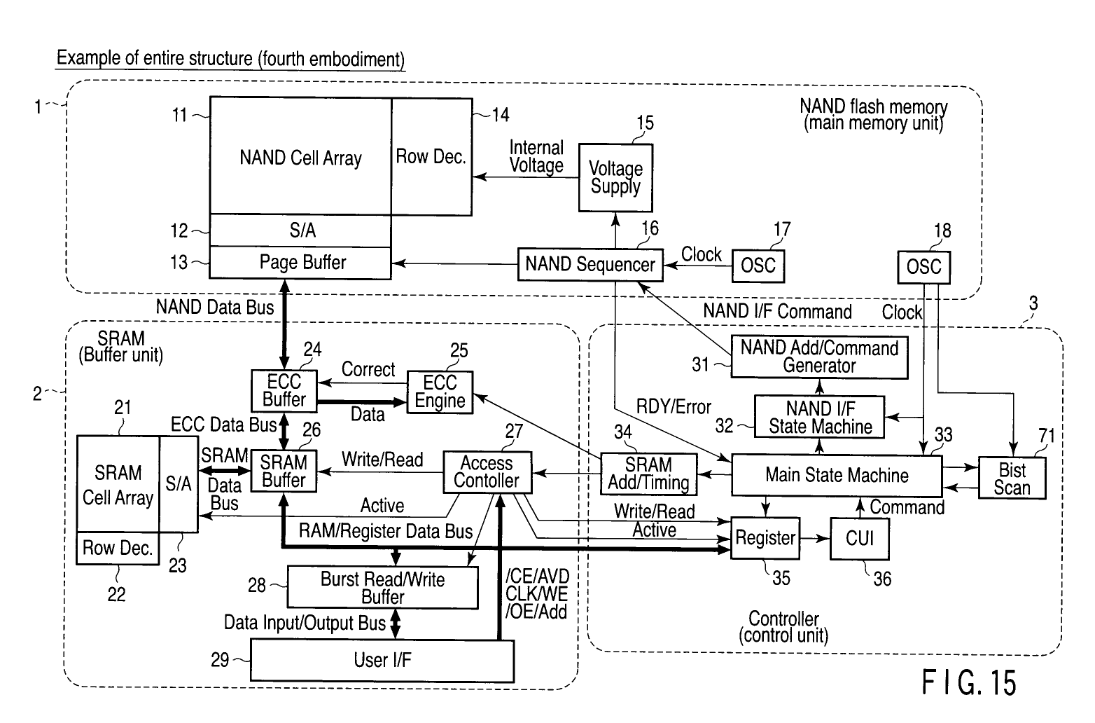

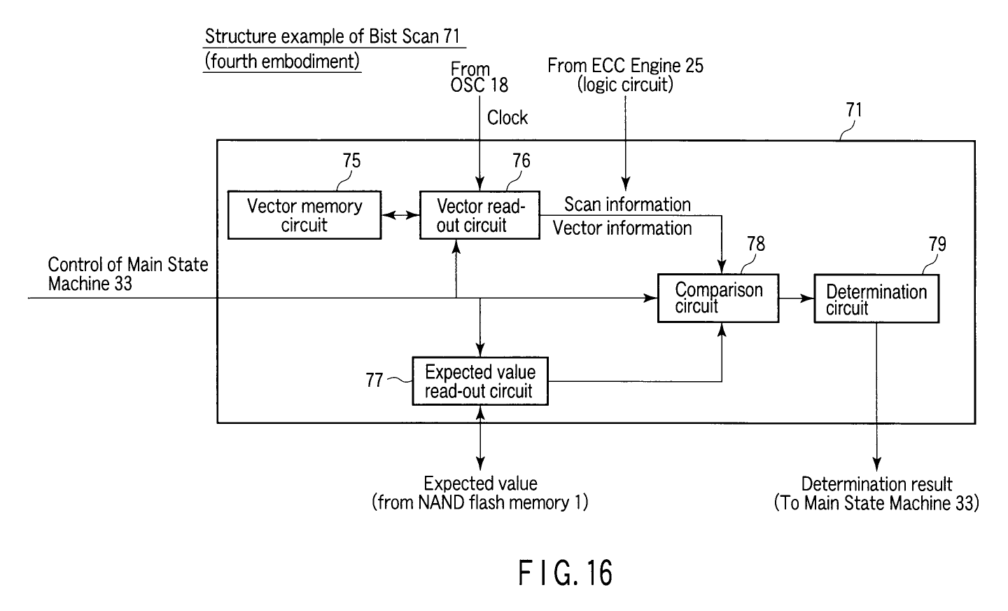

Next, referring to FIG. 15 to FIG. 16, a description is given of a semiconductor memory device according to a fourth embodiment of the invention. This embodiment relates to an example further including a scan test circuit 71 which is suited to Bist. A detailed description of the parts common to those in the first embodiment is omitted here.

### <Example of the Entire Structure>

As shown in FIG. 15, the semiconductor memory device according to the fourth embodiment differs from that of the first embodiment in that the semiconductor memory device of the fourth embodiment further includes a Bist scan circuit (Bist Scan) 71.

### <Structure Example of Bist Scan Circuit 71>

Next, referring to FIG. 16, a structure example of the Bist scan circuit 71 is described. As shown in FIG. 16, the Bist scan circuit 71 of this embodiment comprises a vector memory circuit 75, a vector read-out circuit 76, an expected value read-out circuit 77, a comparison circuit 78 and a determination circuit 79.

By the way, the ECC Engine (logic circuit) 25 has a scan chain inserted to the ECC Engine 25. The scan information is output from an output of the scan chain in response to vector information.

The vector memory circuit 75 stores a vector for a scan test.

The vector read-out circuit 76 outputs vector information, which is read out of the vector memory circuit 75, and scan information, which is sent from a logic circuit such as ECC engine 25, to the comparison circuit 78 in sync with the clock (Clock) of the oscillator 18 in accordance with the control of the main state machine 33. In other words, the vector read-out circuit 76 reads out the vector information and inputs the vector information to an input of the scan chain inserted to the ECC Engine 25.

The expected value read-out circuit 77 reads out an expected value, which is stored, for example, in the NAND flash memory 1, in accordance with the control of the main state machine 33 and NAND interface state machine 32, and outputs the expected value to the comparison circuit 78. The expected value read-out circuit 77 reads out an expected value for the scan test. The expected value is stored in any one of the nonvolatile memory 11, the volatile memory 21, a resister in the controller 3 and a mask ROM, for example.

The comparison circuit 78 compares the input scan information relating to the vector read-out circuit 76, and the expected value which is output from the expected value read-out circuit 77. The comparison circuit 78 compares the scan information with the expected value.

The determination circuit 79 determines an output from the comparison circuit 78 and outputs a determination result to the main state machine 33. The determination circuit 79 outputs a result of the scan test based on an output of the comparison circuit 78. The determination circuit 79 fixes the result of the scan test as Fail if the output of the comparison circuit 78 indicates a defect of the logic circuit 25 at least once.

### <Bist Scan Test Method>

The Bist scan test method according to the present embodiment is performed in the following manner. By the way, the main state machine (Ready/Busy circuit) 33 outputs a Busy signal while the scan test is under execution.

To begin with, if a scan test command is input from the outside via the user interface 29, the command information is latched in the command register 35.

Then, the latched scan test command is input to the main state machine 33 that is the control circuit. The main state machine 33 controls the oscillator 18 and activates the internal clock.

If the internal lock (Clock) from the oscillator 18 is input to the Bist scan circuit (Bist Scan) 71, the Bist scan test is started.

Specifically, in accordance with the control of the main state machine 33, the vector read-out circuit 76 successively reads out vector information from the vector information memory circuit 75.

Subsequently, in sync with the internal clock from the oscillator 18, the vector read-out circuit 76 transfers to the comparison circuit 78 the read-out vector information and the scan information from, e.g. the ECC engine 25 that is the logic circuit. As described above, the vector information is sent in a chained fashion to the comparison circuit 78 in sync with the internal clock. In addition, a scan output, which is composed of the vector and the scan information corresponding to the logic circuit such as the ECC engine 25, is successively output from the vector read-out circuit 76.

Subsequently, in accordance with the control of the main state machine 33, the expected value read-out circuit 77 outputs to the comparison circuit 78 the expected value that is read out of, e.g. the NAND flash memory 1.

Then, the comparison circuit 78 compares the scan output, which is input from the vector read-out circuit 76, and the expected value information which is output from the expected value read-out circuit 77. For example, if the scan output and the expected value information agree, “0” data is output. If the scan output and the expected value information do not agree, “1” data is output. If “1” data is output at least once, an output, which fixes the resultant “1” data, is input to the determination circuit 79.

Subsequently, if the determination circuit output of the determination circuit 79 is, e.g. “1” data, the determination result of “test defect” of the logic circuit, such as the ECC engine 25, is sent to, e.g. an external conventional Bist tester via the main state machine 33. If the determination circuit output of the determination circuit 79 is, e.g. “0” data, the determination result of “test OK” is sent to the Bist tester via the main state machine 33. Thus, the test is finished.

During the time period from the reception of the scan test command to the end of the test, the main state machine 33, which functions as a ready/busy (Ready/Busy) circuit, outputs busy (Busy) information to the outside. After the end of the test, the main state machine 33 switches the busy (Busy) information to the ready (Ready) information, and outputs the ready information to the outside.

Thus, in the case of using, e.g. the conventional Bist (Bist) tester, it should suffice if the Bist tester, or the like, sends the scan test command to the Bist scan circuit 71, and receives a determination result of OK/NG from the determination circuit 79 after the change of the status from the busy state to the ready state (Busy→Ready). Therefore, the screening test can be executed with the conventional Bist tester, and the Bist scan test of components including the logic circuit such as ECC engine 25 can be executed.

If the internal clock (Clock) from the oscillator 18 is replaced with an external clock, the information that is read out of the vector read-out circuit 76 is replaced as an external output and the data that is sent to the comparison circuit 78 is directly output to the outside, an ordinary scan test can be executed. At this time, if a fault analysis simulation, etc., is applied, there are such merits that a fault in a defective product can be specified, and physical analysis or the like can be performed to specify a defective layer or to provide a measure to improve the manufacturing process.

The locations of storage of the vector information and expected value are not limited to the examples described above. The vector information and expected value may be stored, for example, in the register 35, mask ROM, or SRAM memory 2, in accordance with the memory capacity.

### Advantageous Effects of the Fourth Embodiment

With the above-described semiconductor memory device according to the present embodiment, the same advantageous effect (1) as described above can be obtained. Furthermore, in the present embodiment, at least the following advantageous effect (4) can be obtained.

(4) A self test can be executed for a logic circuit, and the increase in number of pins can be prevented.

In a test of a memory device, most of defects are those of memory cells. Thus, in many cases, in a wafer test, for instance, importance is placed on a test of the entirety of the memory. On the other hand, at the time of this test, logic circuits, such as the ECC engine 25, for operating the memory, are simply operated. Since the defect ratio of the logic circuit such as the ECC engine 25 is sufficiently low, the test of the logic circuit, in many cases, constitutes a test step which is performed in a package test at a product level stage.

However, as regards the memory device, there is a tendency that the circuit scale of the logic circuit unit, such as the ECC engine 25, increases. Thus, in a memory device with a relatively small capacity, the defect ratio of the logic circuit has become no longer negligible. Therefore, there is a tendency that a demand becomes stronger for the implementation of a function for efficiently screening the logic circuit at the stage of the wafer test.

In the wafer test, however, in order to increase the number of simultaneous measurements, a dominant method is a self test (Bist test) which can reduce the number of input pins, and can internally execute a test sequence and determination. Thus, disadvantageously, in this environment, it is difficult to directly introduce the scan test method that is widely used in logic devices. Therefore, it is necessary to constitute a scan test circuit which is suited to the self test of the memory device.

Taking the above-described tendency into account, the present embodiment includes the Bist scan circuit 71 which comprises the vector memory circuit 75, the vector read-out circuit 76, the expected value read-out circuit 77, the comparison circuit 78 and the determination circuit 79.

According to the above-described structure and Bist scan test method, for example, in the case of using a conventional Bist (Bist) tester or the like, it should suffice if the Bist tester, or the like, sends the scan test command to the Bist scan circuit 71, and receives a determination result of OK/NG from the determination circuit 79 after the change of the status from the busy state to the ready state (Busy Ready) Therefore, the screening test can be executed with the conventional Bist tester, and the Bist scan test of components including the logic circuit such as ECC engine 25 can be executed.

In the case where a scan test is conducted, dedicated pins (e.g. the number of pins×1) are further needed. In the present embodiment, however, such a scan test can be performed only with self-test pins (e.g. the number of pins×3). Thus, the dedicated pins (e.g. the number of pins×1) can be dispensed with, and the increase in number of pins can advantageously be prevented.

If the internal clock (Clock) from the oscillator 18 is replaced with an external clock, the information that is read out of the vector read-out circuit 76 is replaced as an external output and the data that is sent to the comparison circuit 78 is directly output to the outside, an ordinary scan test can be executed. At this time, if a fault analysis simulation, etc., is applied, there are such merits that a fault in a defective product can be specified, and physical analysis or the like can be performed to specify a defective layer or to provide a measure to improve the manufacturing process.

By preventing the increase in number of pins, simultaneous tests of many chips can be conducted. In addition, since tests of logic circuits can automatically be performed within individual chips after the input of test commands, a chip with a long test time imposes no restrictions on the other chips. Therefore, the speed of the test operation can be increased.

### [Structure Example of the Block (Block) of NAND Cell Array 11]

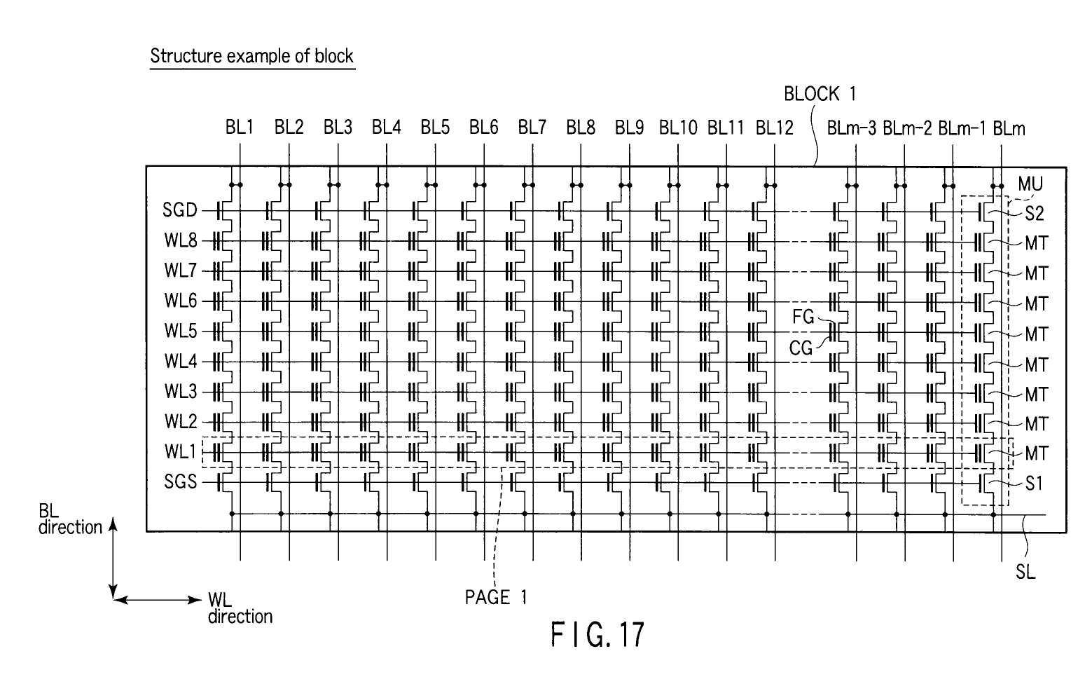

Next, an example of the structure of blocks (BLOCK), which constitute the NAND cell array 11, is described with reference to FIG. 17. In this description, one block BLOCK1 is exemplified. The memory cell transistors in the block BLOCK1 are erased batchwise. In other words, the block is an erase unit.

The block BLOCK1 is composed of a plurality of memory cell strings (memory cell units) MU which are arranged in the word line direction (WL direction). The memory cell string MU comprises a NAND string, which is composed of eight memory cell transistors MT having series-connected current paths, a select transistor S1 which is connected to one end of the NAND string, and a select transistor S2 which is connected to the other end of the NAND string.

In this example, the NAND string is composed of eight memory cells MT. However, the NAND string may be composed of two or more memory cells, and the number of memory cells is not limited to eight.

The other end of the current path of the select transistor S2 is connected to a bit line BLm, and the other end of the current path of the select transistor S1 is connected to a source line SL.

Word lines WL1 to WL8 extend in the WL direction, and are commonly connected to a plurality of memory cell transistors which are arranged in the WL direction. A select gate line SGD extends in the WL direction, and is commonly connected to a plurality of select transistors S2 which are arranged in the WL direction. Similarly, a select gate line SGS extends in the WL direction, and is commonly connected to a plurality of select transistors S1 which are arranged in the WL direction.

Each of the word lines WL1 to WL8 constitutes a unit which is called “page (PAGE)”. For example, as indicated by a broken-line box in FIG. 17, a page 1 (PAGE 1) is allocated to the word line WL1. Since a data read operation and a data write operation are executed in units of the page, the page is a data read unit and a data write unit. In the case of a multilevel memory cell which can store a plurality of bits in one memory cell, a plurality of pages are allocated to one word line.

Each memory cell MT is provided at an intersection between the associated bit line BL and word line WL. The memory cell MT has a multi-layer structure in which a tunnel insulation film, a floating electrode FG functioning as a charge accumulation layer, an intergate insulation film and a control electrode CG are successively provided on a semiconductor substrate. The source/drain, which is a current path of the memory cell MT, is connected in series to the source/drain of the neighboring memory cell MT. One end of the current path is connected to the bit line BLm via the select transistor S2, and the other end of the current path is connected to the source line SL via the select transistor S1.

Each of the memory cells MT has spacers which are provided along side walls of the multi-layer structure, and a source and a drain which are provided in the semiconductor substrate (Si substrate (Si-sub) or a P well) in a manner to sandwich the multi-layer structure.

The select transistor S1, S2 includes a gate insulation film, an inter-gate insulation film, and a gate electrode. The inter-gate insulation film of the select transistor S1, S2 is split at its central part, and the upper and lower layers of the inter-gate insulation film are configured to be electrically connected. The select transistor S1, S2 similarly includes spacers which are provided along side walls of the gate electrode, and a source and a drain which are provided in the semiconductor substrate in a manner to sandwich the gate electrode.

The structure example is not limited to the third embodiment and fourth embodiment. It is possible to combine the structures according to the third embodiment and fourth embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a nonvolatile memory functioning as a main memory unit;
a volatile memory functioning as a buffer unit of the nonvolatile memory;
a controller which controls data transfer between the nonvolatile memory and the volatile memory;
an ECC buffer which is provided between the nonvolatile memory and the volatile memory and is capable of storing main data and parity data;
a parity syndrome circuit which executes parity generation by using the main data transferred to the ECC buffer from the volatile memory, and executes syndrome generation by using the main data and parity data transferred to the ECC buffer from the nonvolatile memory;
an ECC control circuit which controls the parity syndrome circuit and executes timing control of the parity data generation and the syndrome generation;
a multiplexer which effects, when a first test signal is input, switching from an output of the parity syndrome circuit to an output of the ECC buffer, and produces the output of the ECC buffer; and
an ECC error position decoder which has an input connected to an output of the multiplexer, and has an output connected to the ECC buffer.

2. The device according to claim 1, wherein the controller includes:
a timing generating circuit which executes timing generation for the volatile memory;
a main address generating circuit which outputs an address of the main data;
a parity address generating circuit which outputs an address of the parity data; and
a multiplexer which effects, when a second test signal is input, switching from the address of the main data to the address of the parity data, and outputs the address of the parity data to the volatile memory.

3. The device according to claim 2, wherein the volatile memory is an SRAM and a size of the parity data generated by the parity syndrome circuit is greater than a size of parity area in the SRAM provided as external specifications.

4. The device according to claim 2, wherein the nonvolatile memory is a NAND flash memory.

5. The device according to claim 4, wherein the NAND flash memory comprises a memory cell array and a page buffer, the page buffer is capable of storing the main data and parity data to be written into or read from the memory cell array.

6. The device according to claim 5, wherein when the first test signal is input, a test pattern transferred to the page buffer from the ECC buffer is not written into the memory cell array and the parity data is not added to the test pattern.

7. The device according to claim 5, wherein when the second test signal is input, a test pattern as the main data and the parity data transferred to the page buffer from the ECC buffer is not written into the memory cell array.

8. A test method of a semiconductor memory device, comprising:
writing a test pattern in a volatile memory;
transferring the test pattern from the volatile memory to an ECC buffer;
generating parity data by using the test pattern which is stored in the ECC buffer;
transferring the test pattern and the parity data from the ECC buffer to a page buffer of a nonvolatile memory;
transferring the test pattern and the parity data from the page buffer to the ECC buffer, without writing the test pattern and the parity data into a memory cell array of the nonvolatile memory; and
transferring at least the parity data, which is stored in the ECC buffer, to the volatile memory.

9. The method according to claim 8, wherein when transferring the parity data to the volatile memory, at least a part of the parity data, which is stored in the ECC buffer, is transferred to main address region of the volatile memory.

10. The method according to claim 9, wherein a part of a program function operation for user data is diverted to transfer of the test pattern to the page buffer from the ECC buffer.

11. The method according to claim 9, wherein a part of a load function operation for user data is diverted to transfer of the test pattern to the ECC buffer from the page buffer.

12. The method according to claim 11 further comprising:
reading out the parity data to an external tester from the volatile memory; and
comparing the parity data with an expected value which is calculated from the test pattern.

13. A semiconductor memory device comprising:
a nonvolatile memory functioning as a main memory unit;
a volatile memory functioning as a buffer unit of the nonvolatile memory;
a controller which controls data transfer between the nonvolatile memory and the volatile memory;
a logic circuit to which a scan chain is inserted, scan information is output from an output of the scan chain in response to vector information;
a vector read-out circuit which read out the vector information and inputs the vector information to an input of the scan chain;
an expected value read-out circuit which reads out an expected value for the scan test;
a comparison circuit which compares the scan information with the expected value; and
a determination circuit which outputs a result of the scan test based on an output of the comparison circuit.

14. The device according to claim 13 further comprising an ECC buffer which is provided between the nonvolatile memory and the volatile memory and is capable of storing main data and parity data, wherein the logic circuit is an ECC engine which executes error correction by generating a parity data by using the main data transferred to the ECC buffer from the volatile memory, and generating a syndrome by using the main data and parity data transferred to the ECC buffer from the nonvolatile memory.

15. The device according to claim 13, wherein the expected value is stored in any one of the nonvolatile memory, the volatile memory, a resister in the controller and a mask ROM.

16. The device according to claim 13, wherein the vector information is stored in any one of the nonvolatile memory, the volatile memory, a resister in the controller and a mask ROM.

17. The device according to claim 13 further comprising a oscillator which generates an internal clock, wherein the vector read-out circuit transfers the vector information to the scan chain synchronizing with the internal clock.

18. The device according to claim 13 further comprising a Ready/Busy circuit which outputs a Busy signal while the scan test is under execution.

19. The device according to claim 13, wherein the determination circuit fixes the result of the scan test as Fail if the output of the comparison circuit indicates a defect of the logic circuit at least once.

20. The device according to claim 19 further comprising input pins for the scan test, wherein the input pins are shared with BIST test of the nonvolatile memory.
